(19) United States
(12) Patent Application Publication
(10) Pub. No.: US 2016/0005654 A1
(43) Pub. Date: Jan. 7, 2016

(54) SYSTEM FOR MANUFACTURING A SEMICONDUCTOR PACKAGE AND METHOD OF MANUFACTURING THE SAME

(71) Applicant: SAMSUNG ELECTRONICS CO., LTD., Suwon-si (KR)

(72) Inventors: Yoon-Seok SONG, Anyang-si (KR); Jun-Young KO, Cheonan-si (KR); Hae-Gu LEE, Asan-si (KR)

(73) Assignee: SAMSUNG ELECTRONICS CO., LTD., Suwon-si (KR)

(21) Appl. No.: 14/636,977

(22) Filed: Mar. 3, 2015

(30) Foreign Application Priority Data
Jul. 3, 2014 (KR) 10-2014-0083116

(51) Int. Cl. H01L 21/78; B23K 26/08; H01L 21/67; B23K 26/38; H01L 21/268; B23K 26/00; B23K 26/14

(52) U.S. Cl. CPC H01L 21/78; B23K 26/0087; B23K 26/08; B23K 26/14; B23K 26/38; H01L 21/268; H01L 21/67115

(57) ABSTRACT

Provided are a system and method for manufacturing a semiconductor package. The system includes: a laser marker configured to irradiate a first laser beam on a strip to make a mark on the strip; and a laser saw configured to irradiate a second laser beam on the strip to cut the strip into individual semiconductor packages.

### CROSS-REFERENCE TO RELATED APPLICATION

This application claims priority from Korean Patent Application No. 10-2014-0083116, filed on Jul. 3, 2014 in the Korean Intellectual Property Office (KIPO), the contents of which are herein incorporated by reference in their entirety.

### BACKGROUND

1. Field

Apparatuses and methods consistent with exemplary embodiments relate to manufacturing a semiconductor package, and more particularly, to manufacturing a semiconductor package configured to perform a marking process and a sawing process.

2. Description of the Related Art

In general, a semiconductor package may be subjected to a solder ball attachment process and a sawing process after a marking process. Since each of the processes may be carried out in independent facilities, a relatively large working space may be utilized.

Additionally, in the sawing process of the semiconductor package, a blade, which is produced by mixing a diamond to ductile metal components, may be used.

However, a poor appearance of the semiconductor package may result because the blade may easily be bent by an impact. Furthermore, deionized water that is used for compensating for the heat by high speed rotation may cause environmental problems.

### SUMMARY

Aspects of one or more exemplary embodiments provide a system for manufacturing a semiconductor package using a laser to perform a marking process and a sawing process.

Aspects of one or more exemplary embodiments also provide a method of manufacturing a semiconductor package using a laser to perform a marking process and a sawing process.

Aspects of one or more exemplary embodiments also provide a system for manufacturing a semiconductor package which performs a marking process and a sawing process in a single manufacturing line.

According to an aspect of an exemplary embodiment, there is provided a system for manufacturing a semiconductor package, the system including: a laser marker configured to irradiate a first laser beam on a strip to make a mark on the strip; and a laser saw configured to irradiate a second laser beam on the strip to cut the strip into individual semiconductor packages.

The laser saw may include: a chuck table configured to support the strip, and a laser beam irradiator configured to irradiate the second laser beam on the strip.

The chuck table may be rotatable to turn the strip over.

The laser saw further may include a pre-heater configured to pre-heat the strip.

The pre-heater may include a nozzle configured to spray hot air on the strip.

The pre-heater may include a pre-heating laser beam irradiator configured to irradiate a nanosecond laser beam on the strip, and the laser beam irradiator may be configured to irradiate, as the second laser beam, a picosecond laser beam on the pre-heated strip.

The pre-heater may include a pre-heating laser beam irradiator configured to irradiate an infrared light laser beam on the strip, and the laser beam irradiator may be configured to irradiate, as the second laser beam, a visible light laser beam on the pre-heated strip.

The system may further include: a transfer mechanism configured to transfer the marked strip to the laser saw, wherein the transfer mechanism may include a rail configured to guide the strip and to turn the strip over.

According to an aspect of another exemplary embodiment, there is provided a method of manufacturing a semiconductor package, the method including: irradiating a first laser beam on a strip to make a mark on the strip; and irradiating a second laser beam on the marked strip to cut the strip into individual semiconductor packages.

The cutting the marked strip may include: loading the strip on a chuck table; and irradiating, by a laser beam irradiator, the second laser beam on the strip loaded on the chuck table.

The method may further include pre-heating the strip.

The pre-heating the strip may include spraying hot air on the strip to pre-heat the strip.

The pre-heating the strip may include irradiating a nanosecond laser beam on the strip to pre-heat the strip, and the irradiating the second laser beam on the strip may include irradiating, as the second laser beam, a picosecond laser beam on the pre-heated strip to cut the strip into the individual semiconductor packages.

The method may further include rotating the chuck table to turn the strip over.

The method may further include transferring the marked strip from a laser marker that irradiates the first laser beam to a laser saw that irradiates the second laser beam, wherein the transferring the marked strip may include rotating the strip to turn the strip over.

According to an aspect of another exemplary embodiment, there is provided a method of manufacturing a semiconductor package, the method including: irradiating, by a laser marker on a manufacturing line, a first laser beam on a strip to make a mark on the strip; and irradiating, by a laser saw on the manufacturing line, a second laser beam on the strip to cut the strip into individual semiconductor packages.

The irradiating the first laser beam and the irradiating the second laser beam may be performed on the strip without removing the strip from the manufacturing equipment.

The irradiating the first laser beam may include irradiating the first laser beam on a first surface of the strip, and the irradiating the second laser beam may include irradiating the second laser beam on a second surface, opposite the first surface, of the strip.

The method may further include pre-heating the strip prior to irradiating the second laser beam on the strip.

The pre-heating the strip may include irradiating a first type laser beam on the strip to pre-heat the strip, and the irradiating the second laser beam on the strip may include irradiating, as the second laser beam, a second type laser beam on the pre-heated strip to cut the strip into the individual semiconductor packages.

### BRIEF DESCRIPTION OF THE DRAWINGS

Exemplary embodiments will be more clearly understood from the following detailed description taken in conjunction with the accompanying drawings. FIGS. 1 to 9 represent non-limiting, exemplary embodiments as described herein.

FIG. 1 is a block diagram illustrating a system for manufacturing a semiconductor package in accordance with an exemplary embodiment.

FIG. 2 is a cross-sectional view illustrating a laser sawing unit of the manufacturing system in FIG. 1.

FIG. 3 is a view illustrating a process of inverting a strip by rotating a chuck table of the laser sawing unit in FIG. 2.

FIG. 4 is a cross-sectional view illustrating a laser sawing unit in accordance with an exemplary embodiment.

FIG. 5 is a cross-sectional view illustrating a laser sawing unit in accordance with an exemplary embodiment.

FIG. 6 is a plan view illustrating a transfer unit of the manufacturing system in FIG. 1.

FIG. 7 is a cross-sectional view cut along the line A-A′ in FIG. 6.

FIG. 8 is a flow chart illustrating a method of manufacturing a semiconductor package in accordance with an exemplary embodiment.

FIG. 9 is a flow chart illustrating a method of manufacturing a semiconductor package in accordance with an exemplary embodiment.

### DETAILED DESCRIPTION OF EXEMPLARY EMBODIMENTS

Various exemplary embodiments will be described more fully hereinafter with reference to the accompanying drawings. Exemplary embodiments may, however, be embodied in many different forms and should not be construed as limited to exemplary embodiments set forth herein. Rather, these exemplary embodiments are provided so that this disclosure will be thorough and complete, and will fully convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Similarly, expressions such as “at least one of” do not necessarily modify an entirety of a following list and do not necessarily modify each member of the list, such that “at least one of a, b, and c” should be understood as including only one of a, only one of b, only one of c, or any combination of a, b, and c.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

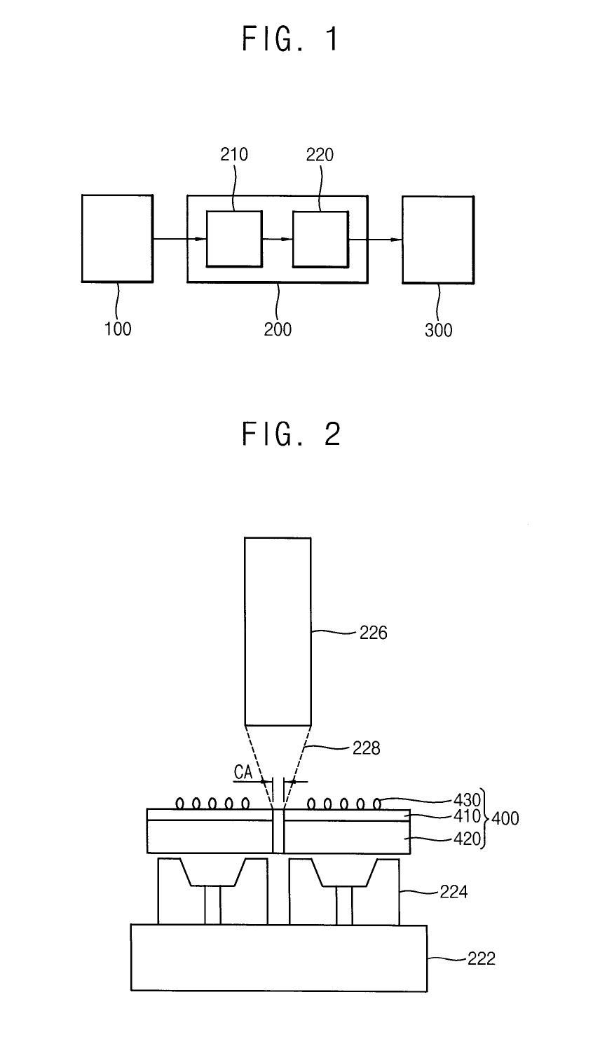

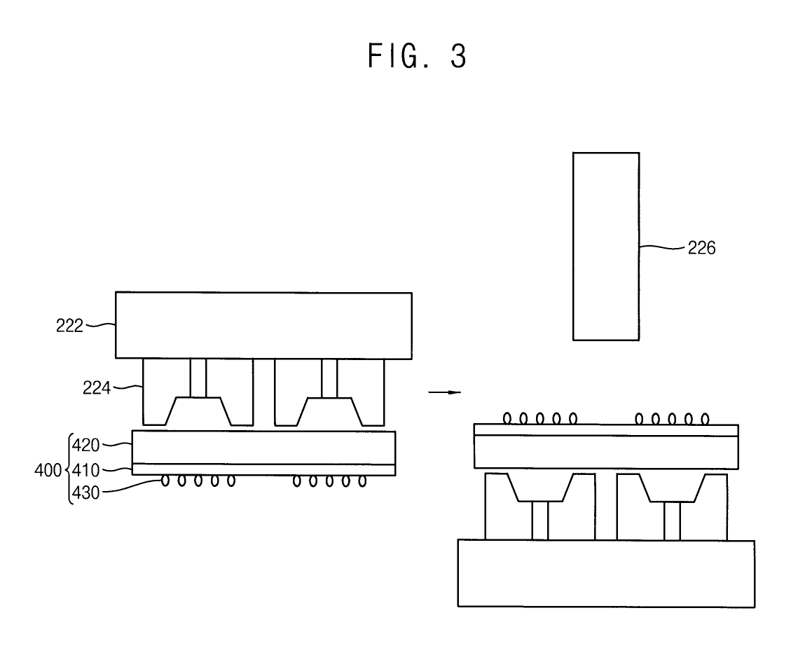

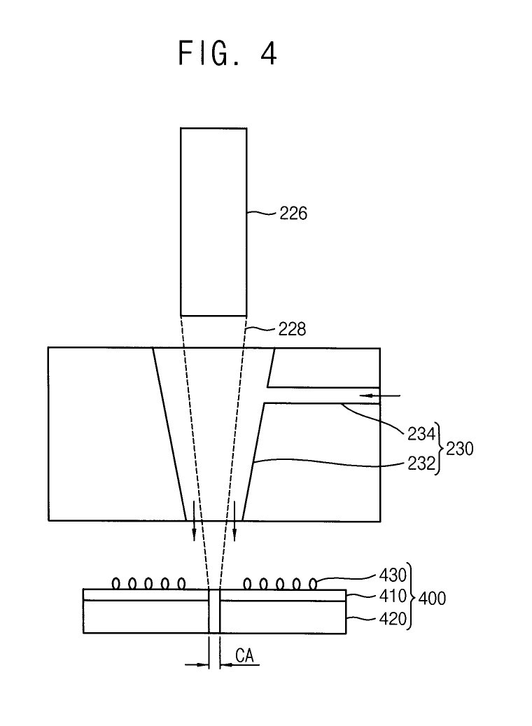

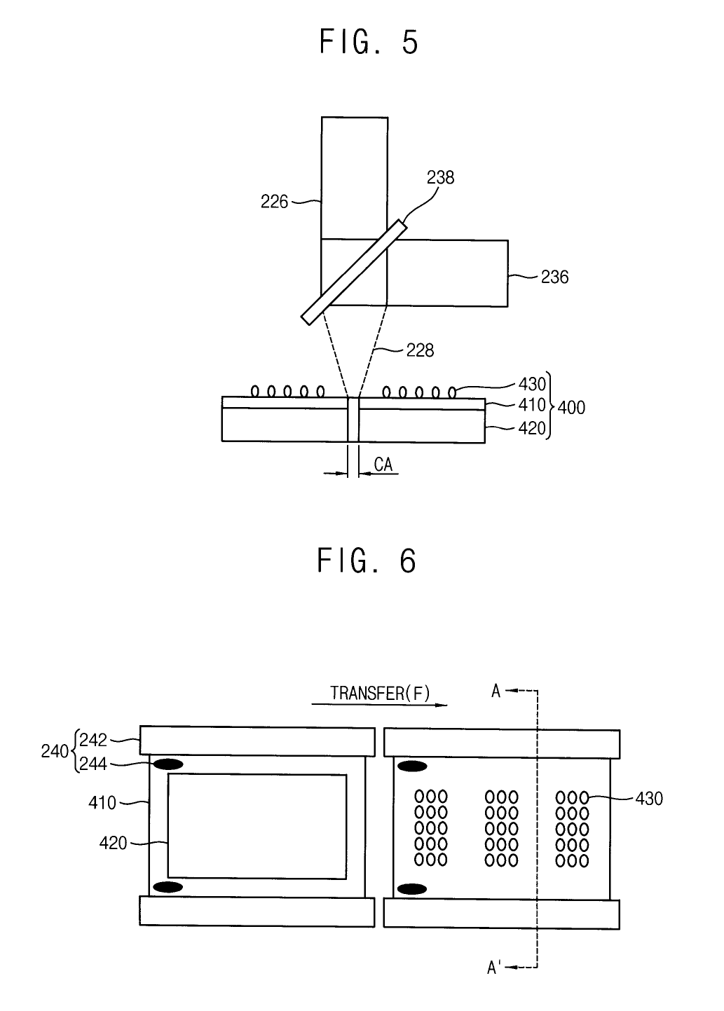

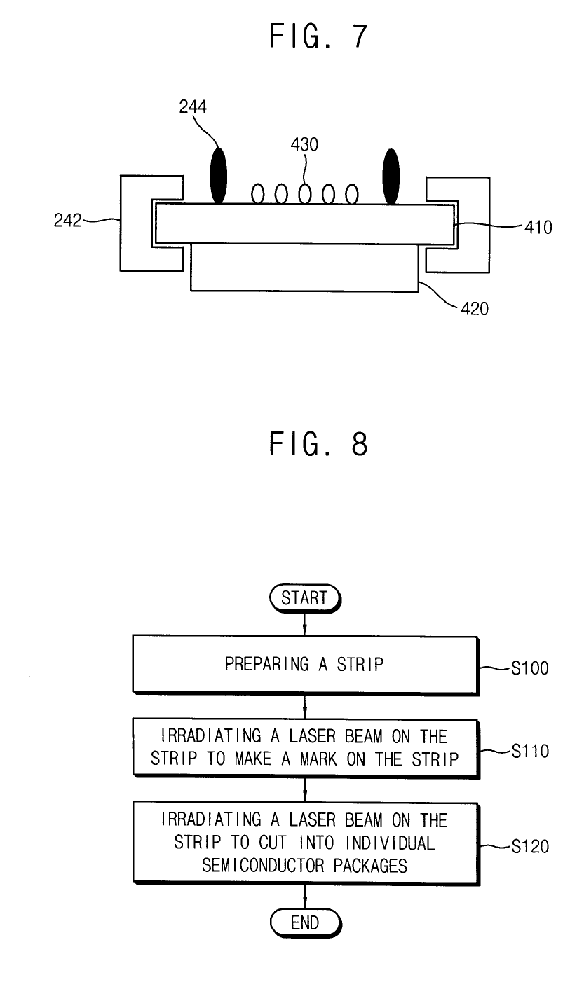

FIG. 1 is a block diagram illustrating a system for manufacturing a semiconductor package in accordance with an exemplary embodiment. FIG. 2 is a cross-sectional view illustrating a laser sawing unit 220 of the manufacturing system in FIG. 1. FIG. 3 is a view illustrating a process of inverting (i.e., turning over) a strip 400 by rotating a chuck table 222 of the laser sawing unit 220 in FIG. 2. FIG. 4 is a cross-sectional view illustrating a laser sawing unit 220 in accordance with an exemplary embodiment. FIG. 5 is a cross-sectional view illustrating a laser sawing unit 220 in accordance with an exemplary embodiment. FIG. 6 is a plan view illustrating a transfer unit of the manufacturing system in FIG. 1. FIG. 7 is a cross-sectional view cut along the line A-A′ in FIG. 6.

Referring to FIGS. 1 to 7, a system for manufacturing a semiconductor package may include a loading unit 100 (e.g., loader) for loading a strip 400, a marking/sawing unit 200 (e.g., marker/saw) for making a mark on (i.e., marking) the loaded strip 400 and cutting the strip 400 into individual semiconductor packages, and an unloading unit 300 (e.g., unloader) for unloading the individual semiconductor package. The marking/sawing unit 200 may include a laser marking unit 210 (e.g., laser marker) for irradiating a laser beam (e.g., first laser beam) on the strip 400 to make a mark on the strip 400, and a laser sawing unit 220 (e.g., laser saw) for irradiating a laser beam (e.g., second laser beam) on the strip 400 to cut the strip 400 into individual semiconductor packages.

According to the present exemplary embodiment, the loading unit 100 may transfer the strip 400, which is ready for sawing in, for example, a magazine, to the laser marking unit 210. For example, the loading unit 100 may include a transfer mechanism including at least one of pushers, guiderails, pickers, grippers, and inlet devices for transferring the strip provided or loaded, for example, in the magazine.

After a molding process and a solder ball attachment process are performed, preliminary semiconductor chips may be attached to a substrate to be provided as a strip form. For example, as illustrated in FIG. 2, the strip 400 may include a strip substrate 410 mounting a plurality of the preliminary semiconductor chips thereon, a molding member 420 covering the preliminary semiconductor chips on an upper surface of the strip substrate 410, and solders 430 (or solder balls) disposed on a lower surface of the strip substrate 410. In this case, the strip substrate 410 may include a printed circuit board (PCB).

The laser marking unit 210 may irradiate a laser beam on the strip 400 to mark various information on the strip 400. The loaded strip 400 may be supported on a stage of the laser marking unit 210, and the laser beam may be irradiated on the loaded strip 400 to mark various information on the molding member 420.

The laser sawing unit 220 may irradiate a laser beam on the strip 400 to cut the strip 400 into the individual semiconductor packages. The laser sawing unit 220 may irradiate a laser beam 228 on the lower surface of the strip substrate 410 (i.e., a surface on which the solders 430 are provided) to cut the strip 400. Since the laser beam 228 is irradiated on the lower surface of the strip substrate 410, thermal influences on the molding member 420 on the upper surface of the strip substrate 410 may be reduced to prevent damage to and thermal deformation of the molding member 420.

The unloading unit 300 may transfer the individual semiconductor packages cut by the laser sawing unit 220 to a tray. For example, the unloading unit 300 may include a transfer mechanism including at least one of pushers, guiderails, pickers, grippers, and inlet devices for transferring the individual semiconductor package.

Referring again to FIG. 2, the laser sawing unit 220 may include a chuck table 222 for supporting the strip 400 and a laser beam irradiator 226 for irradiating a laser beam on the strip 400.

The chuck table 222 may support and hold the strip 400. For example, the chuck table 222 may include a plurality of vacuum suction parts 224 for drawing in or retaining the strip 400 by a vacuum.

The laser beam irradiator 226 may irradiate the laser beam 228 on the strip substrate 410 to cut the strip 400 into individual semiconductor packages. By way of example, this cutting process may be performed by a so-called full-cutting method. In the full-cutting method, a cutting region CA of the strip 400 may be dissolved to evaporate by a high intensity laser beam.

Referring to FIG. 3, the chuck table 222 may rotate to invert (i.e., turn over) the strip 400.

For example, the chuck table 222 may turn over the strip 400 such that the strip substrate 410 of the marked strip 400 faces toward the laser beam irradiator 226 of the laser sawing unit 220. The laser beam irradiator 226 of the laser sawing unit 220 may irradiate a laser beam on the strip substrate 410 of the inverted strip 400 to cut the strip 400 into individual semiconductor packages. The chuck table 222 may rotate again to re-invert the individual semiconductor packages. The unloading unit 300 may transfer the re-inverted individual semiconductor packages to the tray.

Referring to FIG. 4, according to an exemplary embodiment, the laser sawing unit 220 may further include a pre-heating part 230 (e.g., pre-heater or pre-heating device) for pre-heating the strip 400.

The pre-heating part 230 may pre-heat the strip 400 and may save time for cutting the strip 400 using the laser beam irradiated from the laser beam irradiator 226.

The pre-heating part 230 may include an air spraying nozzle 232 for spraying hot air on the strip 400. Hot air from outside may be supplied into the air spraying nozzle 232 through an air supplier 234 of the pre-heating part 230, and then may be sprayed on the cutting area CA of the strip 400 through the air spraying nozzle 232.

Referring to FIG. 5, according to an exemplary embodiment, the pre-heating part 230 may include a pre-heating laser beam irradiator 236 for irradiating a first type laser beam (e.g., a nanosecond laser beam) on the strip 400. In this case, the laser beam irradiator 226 may irradiate a second type laser beam (e.g., a picosecond laser beam) on the pre-heated strip 400.

For example, the pre-heating laser beam irradiator 236 of the pre-heating part 230 may irradiate a laser beam with nanosecond pulse width to pre-heat the strip 400. The nanosecond laser beam irradiated from the pre-heating laser beam irradiator 236 may be directed to the strip 400 by a reflector 238. The reflector 238 may change the propagation direction of the nanosecond laser beam irradiated from the pre-heating laser beam irradiator 236, to direct the nanosecond laser beam to the strip 400. Accordingly, the pre-heated strip 400 may be cut completely into individual semiconductor packages by a picosecond laser beam with picosecond pulse width irradiated from the laser beam irradiator 226.

Furthermore, by way of another example, the pre-heating part 230 may include a pre-heating laser beam irradiator 236 for irradiating an infrared light laser beam on the strip 400, and the laser beam irradiator 226 may irradiate a visible light laser beam on the pre-heated strip 400.

For example, the pre-heating laser beam irradiator 236 of the pre-heating part 230 may irradiate a laser beam of an infrared range having a relatively long wavelength to pre-heat the strip 400. The infrared light laser beam irradiated from the pre-heating laser beam irradiator 236 may be irradiated on the strip 400 by a reflector 238. The reflector 238 may change the propagation direction of the infrared light laser beam irradiated from the pre-heating laser beam irradiator 236, to direct the infrared light laser beam to the strip 400. Accordingly, the pre-heated strip 400 may be cut completely into individual semiconductor packages by a visible light laser beam irradiated from the laser beam irradiator 226. In this case, the visible light laser beam may be a green light laser beam of a visible ray range.

Referring to FIGS. 6 and 7, the system for manufacturing a semiconductor package may further include a transfer unit 240 (e.g., transfer device or transfer mechanism) for transferring the marked strip 400 to the laser sawing unit 220. The transfer unit 240 may include a rail 242 for guiding the strip 400 and rotatable to invert the strip 400.

According to the present exemplary embodiment, the transfer unit 240 may transfer the strip 400 marked by the laser marking unit 210 to the laser sawing unit 220 along a transfer direction F. The strip 400 may move along the rail 242 of the transfer unit 240 along the transfer direction F as strip feeding rollers 244 in contact with the strip substrate 410 rotate.

The laser marking unit 210 may irradiate a laser beam on the molding member 420 of the strip 400 to make a mark, while the laser sawing unit 220 may irradiate a laser beam 228 on the strip substrate 410 of the strip 400 to cut the strip 400 into individual semiconductor packages. The transfer unit 240 may turn over the marked strip 400 such that the strip substrate 410 of the strip 400 faces toward the laser beam irradiator 226 of the laser sawing unit 220. For example, the rail 242 of the transfer unit 240 may guide the strip 400 and may rotate to invert (i.e., turn over) the strip 400.

According to an exemplary embodiment, the system for manufacturing a semiconductor package may further include an inspection unit (e.g., inspector or inspection device) for inspecting the marked strip 400 or the individual semiconductor packages. For example, the inspection unit may include a visual or image inspection device such as a camera.

The system for manufacturing a semiconductor package may further include a sorter unit (e.g., sorter or sorting device) for classifying the individually cut packages. For example, the sorter unit may determine which packages satisfy a particular criteria and transfer packages to the tray only if satisfying the particular criteria. Meanwhile, packages that do not satisfy the particular criteria may not proceed to subsequent processes, thereby lowering the production cost of the semiconductor packages.

As described above, since the laser marking unit 210 and the laser sawing unit 220 may be installed (e.g., provided) in a single manufacturing line in the manufacturing system of the semiconductor package, working space may be saved and the entire working time may be reduced.

Further, since the strip 400 is cut using a laser beam 228 of the laser sawing unit 220, environmental problems due to the deionized water used in the related art blade sawing method may be resolved.

While in the above-described exemplary embodiments, the strip 400 is marked by the laser marking unit 210 before being cut by the laser sawing unit 220, it is understood that one or more other exemplary embodiments are not limited thereto. For example, according to another exemplary embodiment, the strip 400 may be cut by the laser sawing unit 220 before being transferred to the laser marking unit 210.

Hereinafter, a method of manufacturing a semiconductor package using the system for manufacturing a semiconductor package in FIG. 1 will be explained.

FIG. 8 is a flow chart illustrating a method of manufacturing a semiconductor package in accordance with an exemplary embodiment.

Referring to FIG. 8, first, a strip 400 may be prepared (operation S100).

According to an exemplary embodiment, a strip 400 which is ready for sawing in, for example, a magazine may be provided to a laser marking unit 210. For example, a loading unit 100 may hold the strip 400 using a vacuum suction method, may push out the strip 400 using a pusher, and/or may grip the strip 400 using a gripper, to provide the strip 400 to the laser marking unit 210.

Then, a laser beam may be irradiated on the prepared strip 400 to make a mark (operation S110).

According to an exemplary embodiment, the laser beam may be irradiated on the strip 400, which is provided, for example, in the magazine, to mark various information marks on a molding member 420 of the strip 400.

A laser beam 228 may be irradiated on the marked strip 400 to cut the strip 400 into individual semiconductor packages (operation S120).

According to an exemplary embodiment, a laser beam may be irradiated on a strip substrate 410 of the marked strip 400 to cut the strip 400 into individual semiconductor packages. For example, a laser beam 228 having a wavelength range, which is absorbed in the strip substrate 410, may be irradiated on the strip 400, to dissolve and evaporate the strip 400 in order to cut the strip 400. In this case, the laser beam 228 may be irradiated on the strip substrate 410 to reduce thermal influences on the molding member 420, thereby reducing damage and possibility of deformation of the molding member 420.

As described above, a step of marking by irradiating a laser beam and a step of sawing by irradiating a laser beam 228 may be performed sequentially in a single manufacturing line for a semiconductor package. Thus, working space may be saved and the entire working time may be reduced.

According to an exemplary embodiment, the operation S120 of cutting the marked strip 400 may include an operation of loading the marked strip 400 on a chuck table 222 and an operation of irradiating the laser beam 228 generated from a laser beam irradiator 226 on the strip of the chuck table.

A related art cutting method using a blade may cut the strip only in the vertical direction or the horizontal direction. Thus, the marked strip 400 should be aligned through a rotation correction after being loaded on the chuck table 222. In contrast, in the cutting method using the laser beam 228, the marked strip 400 may be cut in the diagonal direction without the rotation correction.

According to an exemplary embodiment, the method of manufacturing a semiconductor package may further include an operation of pre-heating the strip 400. The operation of cutting the strip 400 by irradiating the laser beam 228 on the strip 400 may irradiate a high intensity laser beam 228 on the strip substrate 410 of the strip 400, to dissolve and evaporate the strip substrate 410 in order to cut the strip 400 into individual semiconductor packages. Thus, through pre-heating the strip 400 on which the laser beam 228 is irradiated, the strip 400 may be cut at a faster rate to reduce the time for the cutting.

According to an exemplary embodiment, the operation of pre-heating the strip 400 may include an operation of spraying hot air on the strip 400 to pre-heat the strip 400. For example, an air spraying nozzle 232 illustrated in FIG. 4 may pre-heat the strip 400.

According to an exemplary embodiment, the operation of pre-heating the strip 400 may include an operation of irradiating a nanosecond laser beam on the strip 400 to pre-heat the strip 400, and the operation of irradiating the laser beam 228 may include an operation of irradiating a picosecond laser beam on the pre-heated strip 400 to cut the strip 400 into individual semiconductor packages.

For example, a laser beam with a nanosecond pulse width may be irradiated on the marked strip 400 to pre-heat the strip 400. Furthermore, a laser beam with a picosecond pulse width may be irradiated on the pre-heated strip 400 to cut the strip 400 into individual semiconductor packages.

According to an exemplary embodiment, the operation of pre-heating the strip may include an operation of irradiating an infrared light laser beam on the strip 400, and the operation of irradiating the laser beam 228 may include an operation of irradiating a visible light laser beam on the pre-heated strip 400 to cut the strip 400 into individual semiconductor packages.

For example, a laser beam of an infrared range having a relatively long wavelength may be irradiated on the marked strip 400 to pre-heat the strip 400. Then, a laser beam of a visible ray range may be irradiated on the pre-heated strip 400 to cut the strip 400 into individual semiconductor packages. In this case, the visible light laser beam may be a green light laser beam of the visible ray range.

As described above, the method of manufacturing a semiconductor package may irradiate a laser beam 228 on the strip 400 to cut the strip 400 into individual semiconductor packages after pre-heating the marked strip 400. Thus, the working time and thermal influences on the cutting region may be reduced. In this case, the operation of pre-heating the strip 400 may be performed by hot air, a nanosecond laser beam, or an infrared light laser beam. Additionally, the operation of cutting the strip 400 may be performed by a picosecond laser beam or a visible light laser beam.

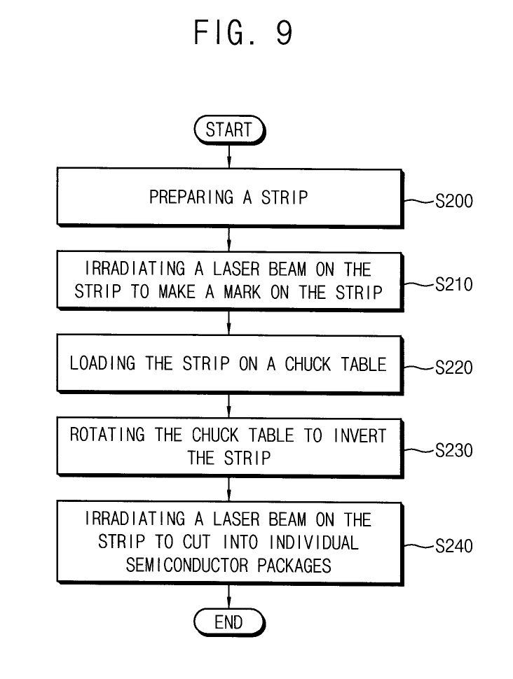

FIG. 9 is a flow chart illustrating a method of manufacturing a semiconductor package in accordance with an exemplary embodiment.

Referring to FIG. 9, a strip 400 may be prepared (operation S200).

According to an exemplary embodiment, a strip 400 which is ready for sawing in, for example, a magazine may be provided to a laser marking unit 210. For example, a loading unit 100 may hold the strip 400 using a vacuum suction method, may push out the strip 400 using a pusher, and/or may grip the strip 400 using a gripper, to provide the strip 400 to the laser marking unit 210.

Then, a laser beam may be irradiated on the prepared strip to make a mark (operation S210).

According to an exemplary embodiment, the laser beam may be irradiated on a molding member 420 of the strip 400 provided, for example, in the magazine, to make various information marks on the molding member 420 of the strip 400.

The marked strip 400 may be loaded on a chuck table 222 (operation S220).

According to an exemplary embodiment, the chuck table 222 may support and hold the strip 400. For example, the chuck table 222 may include a plurality of vacuum suction parts 224 for holding the strip 400.

Then, the strip 400 may be inverted (operation S230).

According to an exemplary embodiment, as illustrated in FIG. 3, the chuck table 22 may rotate to invert the strip 400. Accordingly, a strip substrate 410 of the strip 400 may be turned over such that the strip substrate 410 of the strip 400 faces toward a laser beam irradiator 226 of the laser sawing unit 220.

Then, a laser beam 228 may be irradiated on the inverted strip 400 to cut the strip 400 into individual semiconductor packages (operation S240).

According to an exemplary embodiment, a laser beam 228 may be irradiated on the strip substrate 410 of the inverted strip 400 to cut the strip 400 into individual semiconductor packages. For example, a laser beam having a wavelength range, which is absorbed in the strip substrate 410, may be irradiated on the strip 400, to dissolve and evaporate the strip 400 in order to cut the strip 400. In this case, the laser beam may be irradiated on the strip substrate 410 to reduce thermal influences on the molding member 420, thereby reducing damage and possibility of deformation of the molding member 420.

As described above, the method of manufacturing a semiconductor package may invert the strip 400 by rotation of the chuck table 222. Accordingly, an operation of marking by irradiating a laser beam on the strip 400 and an operation of sawing by irradiating a laser beam 228 on the strip 400 may be performed sequentially in a single manufacturing line in the manufacturing system of the semiconductor package, working space may be saved and the entire working time may be reduced.

According to an exemplary embodiment, the method of manufacturing a semiconductor package may further include an operation of transferring the marked strip 400 to the chuck table 222, and the operation of transferring the marked strip 400 may include an operation of rotating the strip 400 to invert the strip 400.

For example, the method of manufacturing a semiconductor package may include an operation of transferring the marked strip 400 to the chuck table 222 by a transfer unit 240 illustrated in FIG. 6. In this case, a rail 242 illustrated in FIG. 6 may guide the strip 400 and rotate to turn over the strip 400. The inverted strip 400 may be loaded on the chuck table 222, and the strip substrate 410 of the strip 400 may face toward the laser beam irradiator 226 of the laser sawing unit 220.

As described above, the method of manufacturing a semiconductor package may invert the marked strip 400 after the operation of irradiating a laser beam on the strip 400 to make a mark (operation S210). Thus, the strip substrate 410 of the strip 400 may face toward the laser beam irradiator 226 of the laser sawing unit 220.

According to an exemplary embodiment, the method of manufacturing a semiconductor package may further include an operation of inspecting the marked strip 400 or the individual semiconductor packages.

For example, the operation of inspecting the marked strip 400 or the individual semiconductor packages may be performed by a visual or image inspection device such as a camera. The strip 400 or the packages which satisfy particular criteria (e.g., predetermined criteria) may continue to proceed to the next operation, while the strip 400 or the packages that do not satisfy the particular criteria may not continue to the next operation to save unnecessary cost and time.

According to an exemplary embodiment, a system for manufacturing a semiconductor package may include a first laser unit and a second laser unit arranged in a same line with a first laser unit. The first laser unit may irradiate a laser beam on the strip 400 to make a mark on a strip 400, and a second laser unit may irradiate a laser beam 228 on the strip 400 to cut the strip 400 into individual semiconductor packages.

For example, a laser beam irradiated from the first laser unit may make a mark on the strip 400, and a laser beam irradiated from the second laser unit arranged in a same line with the first laser unit may cut the strip 400 into individual semiconductor packages. The first and second laser units may be arranged in the same equipment in the manufacturing system of the semiconductor package. As a result, working space may be saved and productivity of the semiconductor package may be enhanced.

According to another exemplary embodiment, the first laser unit may irradiate a laser beam 228 on the strip 400 to cut the strip 400 into individual semiconductor packages, and the second laser unit may irradiate a laser beam on the individual semiconductor packages to make a mark. Furthermore, according to another exemplary embodiment, the chuck table 222 that is rotatable to turn over the strip 400 may be included in the laser marking unit 210.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages of the present inventive concept. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A system for manufacturing a semiconductor package, the system comprising:
a laser marker configured to irradiate a first laser beam on a strip to make a mark on the strip; and
a laser saw configured to irradiate a second laser beam on the strip to cut the strip into individual semiconductor packages.

2. The system for manufacturing a semiconductor package of claim 1, wherein the laser saw comprises:
a chuck table configured to support the strip; and
a laser beam irradiator configured to irradiate the second laser beam on the strip.

3. The system for manufacturing a semiconductor package of claim 2, wherein the chuck table is rotatable to turn the strip over.

4. The system for manufacturing a semiconductor package of claim 2, wherein the laser saw further comprises a pre-heater configured to pre-heat the strip.

5. The system for manufacturing a semiconductor package of claim 4, wherein the pre-heater comprises a nozzle configured to spray hot air on the strip.

6. The system for manufacturing a semiconductor package of claim 4, wherein:
the pre-heater comprises a pre-heating laser beam irradiator configured to irradiate a nanosecond laser beam on the strip; and
the laser beam irradiator is configured to irradiate, as the second laser beam, a picosecond laser beam on the pre-heated strip.

7. The system for manufacturing a semiconductor package of claim 4, wherein:
the pre-heater comprises a pre-heating laser beam irradiator configured to irradiate an infrared light laser beam on the strip; and
the laser beam irradiator is configured to irradiate, as the second laser beam, a visible light laser beam on the pre-heated strip.

8. The system for manufacturing a semiconductor package of claim 1, further comprising:
a transfer mechanism configured to transfer the marked strip to the laser saw,
wherein the transfer mechanism comprises a rail configured to guide the strip and to turn the strip over.

9. A method of manufacturing a semiconductor package, the method comprising:
irradiating a first laser beam on a strip to make a mark on the strip; and
irradiating a second laser beam on the marked strip to cut the strip into individual semiconductor packages.

10. The method of claim 9, wherein the cutting the marked strip comprises:
loading the strip on a chuck table; and
irradiating, by a laser beam irradiator, the second laser beam on the strip loaded on the chuck table.

11. The method of claim 10, further comprising pre-heating the strip.

12. The method of claim 11, wherein the pre-heating the strip comprises spraying hot air on the strip to pre-heat the strip.

13. The method of claim 11, wherein:
the pre-heating the strip comprises irradiating a nanosecond laser beam on the strip to pre-heat the strip; and
the irradiating the second laser beam on the strip comprises irradiating, as the second laser beam, a picosecond laser beam on the pre-heated strip to cut the strip into the individual semiconductor packages.

14. The method of claim 10, further comprising rotating the chuck table to turn the strip over.

15. The method of claim 9, further comprising:
transferring the marked strip from a laser marker that irradiates the first laser beam to a laser saw that irradiates the second laser beam,
wherein the transferring the marked strip comprises rotating the strip to turn the strip over.

16. A method of manufacturing a semiconductor package, the method comprising:
irradiating, by a laser marker of a manufacturing line, a first laser beam on a strip to make a mark on the strip; and
irradiating, by a laser saw of the manufacturing line, a second laser beam on the strip to cut the strip into individual semiconductor packages.

17. The method of claim 16, wherein the irradiating the first laser beam and the irradiating the second laser beam are performed on the strip without removing the strip from the manufacturing line.

18. The method of claim 16, wherein:
the irradiating the first laser beam comprises irradiating the first laser beam on a first surface of the strip; and
the irradiating the second laser beam comprises irradiating the second laser beam on a second surface, opposite the first surface, of the strip.

19. The method of claim 16, further comprising pre-heating the strip prior to irradiating the second laser beam on the strip.

20. The method of claim 19, wherein:
the pre-heating the strip comprises irradiating a first type laser beam on the strip to pre-heat the strip; and
the irradiating the second laser beam on the strip comprises irradiating, as the second laser beam, a second type laser beam on the pre-heated strip to cut the strip into the individual semiconductor packages.
